(19) United States
(12) Patent Application Publication
(10) Pub. No.: US 2026/0026354 A1
(43) Pub. Date: Jan. 22, 2026

(54) METHOD OF MANUFACTURING SEMICONDUCTOR DEVICES AND CORRESPONDING SEMICONDUCTOR DEVICE

(71) Applicant: STMicroelectronics International N.V., Geneva (CH)

(72) Inventors: Federico LEONE, Lodi, LO (IT); Claudio ZAFFERONI, Milano (IT)

(73) Assignee: STMicroelectronics International N.V., Geneva (CH)

(21) Appl. No.: 19/269,876

(22) Filed: Jul. 15, 2025

(30) Foreign Application Priority Data
Jul. 18, 2024 (IT) 102024000016705

(51) Int. Cl. H01L 23/00; H01L 21/3213; H01L 21/56; H01L 23/31; H01L 23/495

(52) U.S. Cl. CPC H01L 23/562; H01L 21/32136; H01L 21/32139; H01L 21/565; H01L 23/3121; H01L 23/49503; H01L 23/49582; H01L 23/49586; H01L 24/08; H01L 24/48; H01L 2224/08245; H01L 2224/48245

(57) ABSTRACT

A semiconductor die is arranged at a mounting region of a surface of a substrate. A substrate includes electrically conductive leads around a die pad including a mounting region. A metallic layer is located at one or more portions of the substrate including the mounting region. A semiconductor die is arranged at a mounting region. The metallic layer is selectively exposed at portions less than all of the metallic layer to an oxidizing plasma to produce a patterned oxide layer including oxides of metallic material in the metallic layer. An electrically insulating encapsulation is molded onto the surface of the substrate to encapsulate the semiconductor die. The oxides of metallic material in the patterned oxide layer facilitate adhesion of the electrically insulating encapsulation to the surface of the substrate.

### PRIORITY CLAIM

This application claims the priority benefit of Italian Application for Patent No. 102024000016705 filed on Jul. 18, 2024, the content of which is hereby incorporated by reference in its entirety to the maximum extent allowable by law.

### TECHNICAL FIELD

The description relates to semiconductor devices.

One or more embodiments can be applied to semiconductor devices including integrated circuits (ICs) with a quad-flat (QFP) or a quad-flat no leads (QFN) package.

### BACKGROUND

In leadframe based semiconductor devices, a protective plastic package is provided by molding an electrically insulating molding compound onto a semiconductor die (or chip) arranged on a leadframe.

The plastic package protects the (integrated circuit—IC) semiconductor die from humidity and/or contaminants that could otherwise damage the die, possibly causing failure of the device.

A common issue in such devices concerns the undesired delamination of the package from the leadframe. A relatively poor adhesion of the electrically insulating molding compound to the leadframe (of a metallic material such as copper, for instance) may undesirably result in detachment (delamination) of the package from the leadframe.

A same issue may arise also when the leadframe has a metallic finishing layer (a silver finishing layer, for instance) formed at its surface. Such a metallic finishing layer may be formed (via plating, for instance) in order to facilitate processing steps such as die attachment and wire bonding.

According to a conventional approach, a non-etching adhesion promotion (NEAP) layer may be formed at the surface of the leadframe in order to enhance adhesion of the molding compound to the leadframe, thus reducing the risk of delamination therebetween. NEAP processing results in the formation of an oxide layer (a silver oxide layer, for instance) at the surface of the leadframe that has an enhanced adhesion with the molding compound.

However, forming a NEAP layer involves exposing the leadframe to a sequence of processing baths that causes the manufacturing process to be time- and cost-ineffective. Moreover, it is observed that a NEAP layer may at least partially dissolve when exposed to acidic processing baths (such as de-flashing or solder plating bath, for instance), thus increasing the risk of delamination between the package and the leadframe

Reference is made to U.S. Pat. Nos. 9,640,466 B1 and 6,040,633 A, as well as United States Patent Publication Nos. 2020/0144075 A1 and 2008/0012101 A1, all of which are incorporated herein by reference, as providing background information in the related technological area.

There is a need in the art to overcome the drawbacks discussed in the foregoing.

### SUMMARY

One or more embodiments relate to a method.

One or more embodiments relate to a corresponding (integrated circuit) semiconductor device.

Solutions as described herein may be applied to leadframe based semiconductor device where a surface metallic layer is formed at (at least a portion of) the surface of the leadframe.

Solutions as described herein involve selectively exposing the surface metallic layer to an oxidizing plasma in order to form an oxide layer at a portion of the surface of the leadframe; the oxide layer formed at the surface of the leadframe enhances adhesion between the leadframe and the molding compound forming the package, thus reducing the risk of delamination therebetween.

In solutions as described herein, selective exposure to the oxidizing plasma may be performed via otherwise conventional apparatus, such as an atmospheric plasma apparatus or a batch plasma apparatus, for instance.

Solutions as described herein may involve attaching a semiconductor die at a surface of a leadframe, providing electrically conductive formations between the die and the leadframe and, subsequently, selectively exposing the metallic finishing layer to an oxidizing plasma.

Solutions as described herein may advantageously be applied to devices having a quad flat package (QFP) or quad flat no-leads (QFN) package, for instance.

### BRIEF DESCRIPTION OF THE DRAWINGS

One or more embodiments will now be described, by way of example only, with reference to the annexed figures, wherein:

FIGS. 1A to 1E are cross-sectional views illustrative of processing steps according to embodiments of the present description applied to a device with a quad flat no-lead (QFN) package, and

FIGS. 2A to 2C and FIGS. 3A to 3C are cross-sectional views illustrative of sequences of processing steps according to embodiments of the present description applied to a quad flat package (QFP).

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

As described in the following, embodiments of the present description involve arranging a semiconductor die on a surface of a substrate (a leadframe, for instance).

Embodiments of the present description may advantageously be applied to substrates of the type suitable for: devices with a quad flat no lead (QFN) package, or devices with a quad flat package (QFP).

The substrates may comprise a metallic layer (a silver layer resulting from NEAP processing steps applied to the substrate, for instance) formed at a least a portion of the surface.

More in detail, embodiments of the present description may advantageously be applied in substrates (QFN or QFP substrates) having the surface: fully covered by the metallic layer (option oftentimes referred to as fully plated substrate), or partially covered by the metallic layer, as it is the case of substrates with a so-called “silver spot” plating (where the reference to silver is merely exemplary of a possible metallic material that can be plated at the surface of the substrate and must not be construed in a limiting sense).

The metallic layer is selectively exposed to an oxidizing plasma to form a patterned oxide layer (comprising oxides of metallic material in the metallic layer) at the surface of the substrate.

As described in the following, according to embodiments of the present description the metallic layer may be exposed to an oxidizing plasma via: an atmospheric plasma apparatus, and/or a batch plasma apparatus and a filtering mask M.

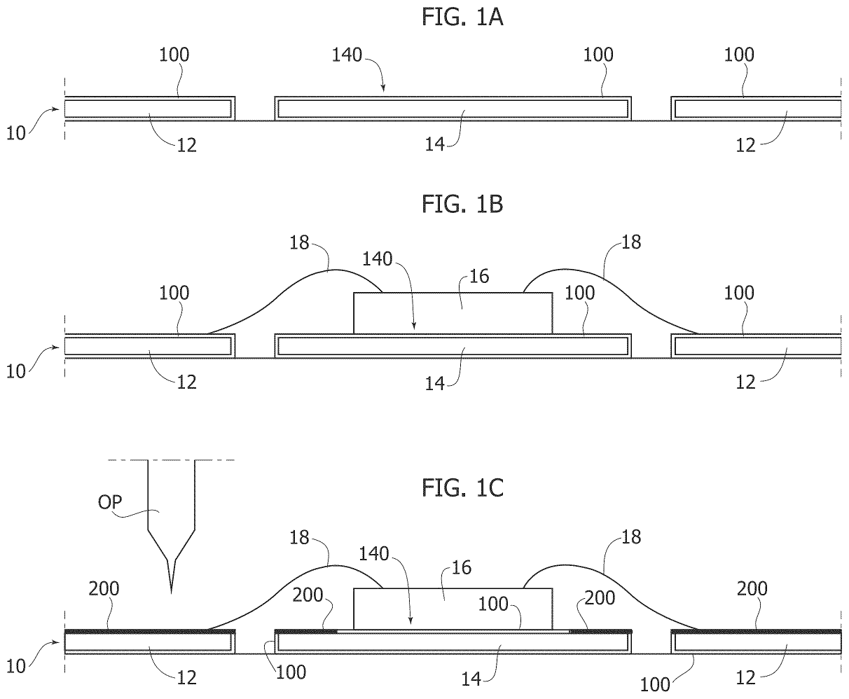

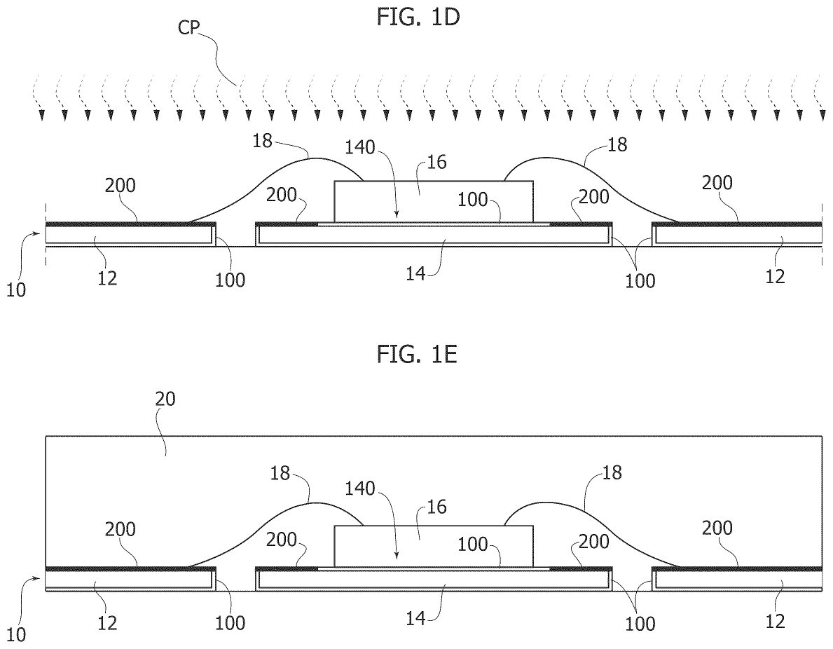

FIGS. 1A to 1E are cross-sectional views illustrative of a sequence of processing steps in a manufacturing process of (integrated circuit-IC) semiconductor devices according to embodiments of the present description.

It is noted that the sequence of steps of FIGS. 1A to 1E is merely exemplary insofar as: one or more steps illustrated in FIGS. 1A to 1E can be omitted, performed in a different manner (with other tools, for instance) and/or replaced by other steps; additional steps may be added; and one or more steps can be carried out in a sequence different from the sequence illustrated.

FIG. 1A is illustrative of a leadframe 10 for semiconductor devices provided on a temporary (and possibly sacrificial) carrier.

The designation “leadframe” (or “lead frame”) is currently used (see, for instance the USPC Consolidated Glossary of the United States Patent and Trademark Office) to indicate a metal frame (copper, for instance) that provides support for an integrated circuit chip or die (the terms chip/chips and die/dice are herein regarded as synonymous) as well as electrical leads to interconnect the integrated circuit in the die or chip to other electrical components or contacts.

Essentially, a leadframe comprises an array of electrically-conductive formations 12 (or leads) that from an outline location extend inwardly in the direction of a semiconductor chip or die (visible in FIG. 1B, for instance, and referenced therein with the reference 16) thus forming an array of electrically-conductive formations from a die pad 14 configured to have at least one semiconductor chip or die attached thereon. This may be via conventional means such as a die attach adhesive (a die attach film (DAF) for instance).

A leadframe 10 can be of the pre-molded type, that is a type of leadframe comprising a sculptured metal (copper, for instance) structure formed by etching a metal sheet and comprising empty spaces that are filled by a resin “pre-molded” on the sculptured metal structure.

An individual leadframe 10 as illustrated in FIG. 1A may be a portion of a common substrate comprising a plurality of such individual leadframes 10. In fact, as known to those skilled in the art, in current manufacturing processes of semiconductor devices, plural devices are manufactured concurrently to be separated into single individual device in a final singulation step. For simplicity and ease of explanation, the following description will refer to manufacturing a single device.

The substrate 10 illustrated in FIG. 1A is exemplary of a leadframe suitable for semiconductor devices of the type oftentimes referred to as quad flat no leads (QFN).

A substrate 10 as illustrated in FIG. 1A is configured to have (at least) one (integrated circuit—IC) semiconductor die or chip (the terms chip/chips and die/dice are herein regarded as synonymous) arranged at a die mounting region 140 of the top/front surface of the substrate 10.

As illustrated, the substrate 10 comprises a metallic layer 100 formed at the surface thereof. The metallic layer 100 may be a metallic finishing layer, for instance, formed (via plating, for instance) over the surfaces (top/front as well as back/bottom surface) of the substrate 10.

The metallic layer 100 may comprise metallic material (silver material for instance) that facilitates subsequent processing steps, such as die mounting and wire bonding steps described in the following.

In the embodiments illustrated in FIGS. 1A to 1E, the metallic layer 100 covers the whole top/front surface of the substrate 10 as well as the bottom/back and side surfaces thereof (“fully plated” substrate). However, the processing steps described with reference to FIGS. 1A to 1E may also be applied in the case of a substrate 10 having a partial (“spot”) plating of the surface thereof (for instance, a metallic layer 100 formed only at the top/front surface of the substrate 10 or at a portion thereof).

FIG. 1B is illustrative of an assembly resulting subsequently to a die mounting step and a wire bonding step. As illustrated, a semiconductor die 16 is arranged at the die mounting region 140 located at the top/front surface 14A of the die pad 14. Die attach material (not visible in the figures for simplicity) such as glue or soft solder, for instance, is provided at the die mounting region 140 in order to facilitate mounting the semiconductor die 16.

Electrically conductive formations 18 (wires, for instance) are provided to electrically couple the semiconductor die 16 to selected leads 12 in the array of electrically conductive leads 12. The electrically conductive formations 18 extend form die bonding pads provided at the top/front surface of the (IC) semiconductor die 16 (the die bonding pads are not visible in the figures for scale reasons) to the top/front surface 12A of the leads 12.

Both die mounting and wire bonding steps are facilitated by the metallic layer 100 (a silver layer, for instance) formed at the surface of the substrate 10.

FIG. 1C is illustrative of a processing step where a portion of the metallic finishing layer 100 is oxidized and an oxide layer 200 is formed at a portion of the top/front surface of the leadframe 10. According to embodiments of the present description such an oxide layer 200 may be formed by exposing selected regions of the metallic layer 100 at the top/front surface of the leadframe 10 to an oxidizing plasma OP. That is, the metallic layer 100 is selectively exposed to an oxidizing plasma OP to form a (patterned) oxide layer 200 at the top/front surface of the leadframe 10.

As illustrated in FIG. 1C, a (patterned) oxide layer 200 may be formed at a portion of the top/front surface of the die pad 14 and/or at a portion of the top/front surface of the leads 12 by exposing the metallic layer 100 formed thereon to an oxidizing plasma OP.

As exemplified in the embodiments illustrated in FIG. 1C, an oxide layer 200 may be formed at a peripheral portion of the die pad 14 around the die mounting region 140 located at a central region of the die pad 14.

The oxide layer 200 may be formed by applying an oxidizing plasma OP to selected portions of the metallic layer 200 formed at the surface of the substrate 10.

Selective exposure to an oxidizing plasma may be achieved via an atmospheric plasma apparatus, as schematically illustrated in FIG. 1C. As known to those skilled in the art, such an apparatus comprises a moving head (or torch) configured to project oxygen ions to a localized region of the workpiece, that is to expose a localized portion of the workpiece (the metallic layer 100, in the case of interest herein) to an oxidizing plasma OP.

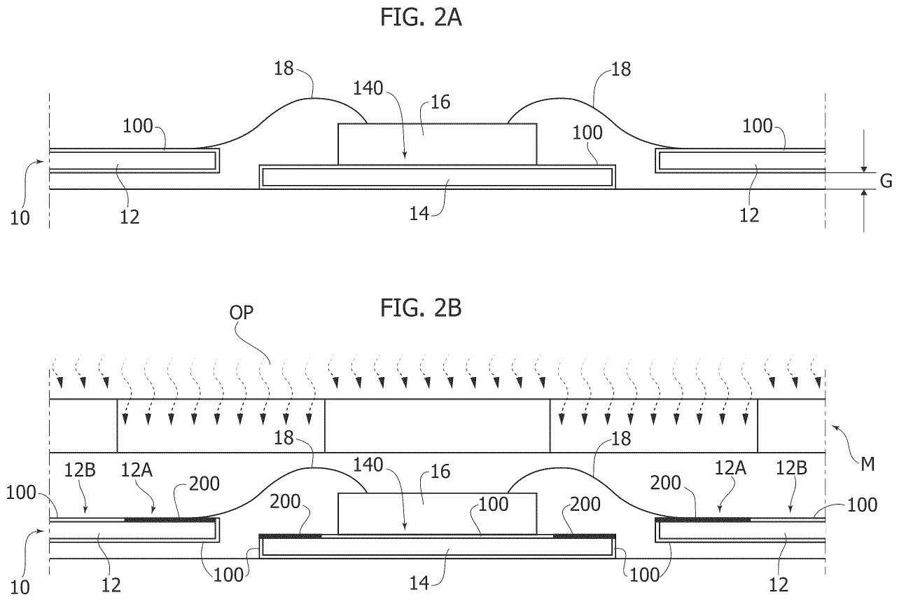

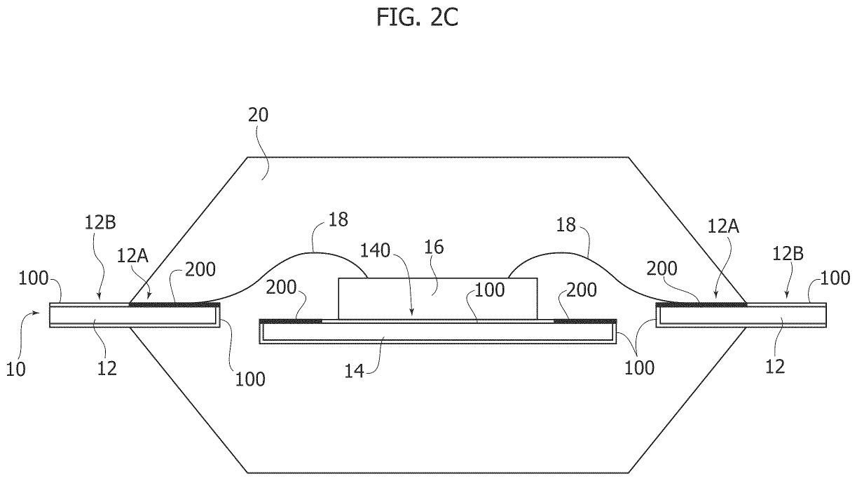

As mentioned, selective exposure to an oxidizing plasma may be achieved also via a batch plasma apparatus with the use of a filtering mask. A substantially uniform oxidizing plasma OP is formed in a vacuum chamber and projected toward the top/front surface of the substrate 10 (having the semiconductor die 16 arranged thereon as well as electrically conductive formations 18 provided between the die 16 and the leads 12). The (substantially) uniform oxidizing plasma OP may be filtered via a filtering mask provided over the substrate 10. The filtering mask counters the oxidizing plasma (that is, oxygen ions formed in the batch plasma chamber) to reach the surface of the substrate 10 at locations where it is not desired to form an oxide layer. Such a processing step is illustrated in FIG. 2B, for instance.

However formed, the resulting (patterned) oxide layer 200 comprises oxides of the metallic material in the metallic layer 100. In embodiments where the metallic layer 100 comprises silver material, the oxide layer 200 formed at selected locations of the top/front surface of the leadframe comprises silver oxides.

It is noted that in FIG. 1C the oxide layer 200 is illustrated as having a thickness equal to the metallic layer 100 only for simplicity. An oxide layer 200 having a different thickness than the metallic layer 100 may be formed.

More in detail, parameters (power input and exposure time, for instance) of the atmospheric plasma apparatus may be chosen to form an oxide layer 200 having a desired thickness. Oxide layer 200 having a thickness in the range between 2 nm to 300 nm may be formed. Advantageously, forming an oxide layer 200 having a thickness between 10 nm and 100 nm has been observed to give satisfactory results in terms of enhanced adhesion between the plastic encapsulation and the leadframe.

It is observed that applying an oxidizing plasma OP to the device subsequently to die mounting and wire bonding steps does not affect the reliability of the die attach and bonding joints at the leads.

FIG. 1D is illustrative of an optional processing step where the device is exposed to a cleaning plasma CP, in order to clean the surface of the leadframe.

As known to those skilled in the art, a cleaning plasma CP may comprise ions (hydrogen and/or argon, for instance) that are projected toward the surface of the substrate in order to get rid of contaminants that may be present at the surface of the substrate 10. A cleaning step as illustrated in FIG. 1D may be carried on via batch plasma equipment, where the surface of the substrate is exposed to a (substantially) uniform cleaning plasma CP.

FIG. 1E is illustrative of a processing step where a protective package 20 is formed by molding an electrically insulating molding compound (an epoxy resin, for instance) onto an assembly as illustrated in FIG. 1D.

As illustrated in FIG. 1E the electrically insulating molding compound 20 contacts the oxide layer 200 formed at the surface of the leadframe 10.

The molding compound 20 has an enhanced adhesion to the oxide layer 200 compared to the metallic layer 100, thus reducing the risk of undesired delamination of the package 20 from the surface of the leadframe 10.

A device as illustrated in FIG. 1E is configured to be mounted on a support (a printed circuit board, PCB, for instance) by providing solder material at the bottom/back surface of the die pad 14 and the leads 12.

To that effect, the metallic layer 100 provided at the bottom/back surface of the substrate 10 may be removed prior to providing solder material at the bottom/back surface of the.

FIGS. 2A to 2C are cross-sectional views illustrative of a sequence of processing steps in a manufacturing process according to embodiments of the present description applied to semiconductor device having a so-called quad-flat package (QFP).

Again, the sequence of steps of FIGS. 2A to 2C is merely exemplary insofar as one or more steps additional steps may be added and one or more steps can be carried out in a sequence different from the sequence illustrated.

An (integrated circuit—IC) semiconductor die 16 is mounted at a die mounting region 140 of a substrate/leadframe 10 provided on a temporary (and possibly sacrificial) carrier. A desired electrical coupling pattern is provided between the semiconductor die 16 and selected leads 12 via wire bonding 18.

As illustrated, in a substrate 10 (leadframe) as considered in embodiments as illustrated in FIGS. 2A to 2C the die pad 14 may be provided at a downset G with respect to the leads 12.

Similar to what has been described in relation to FIG. 1A, the leadframe 10 illustrated in FIG. 2A has a metallic layer 100 formed (via plating, for instance) at the surface thereof in order to facilitate die mounting and wire bonding steps. The surface metallic layer 100 may comprise, for instance, silver material.

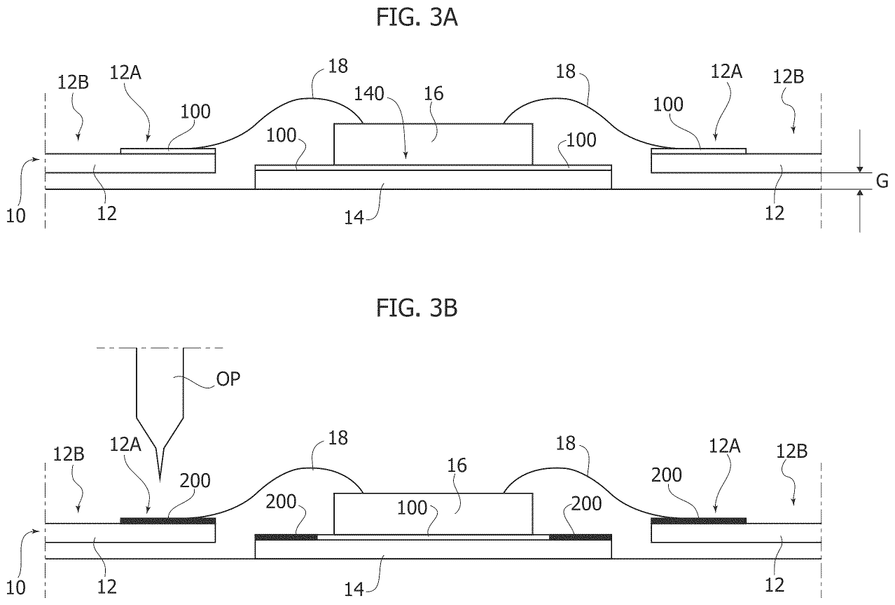

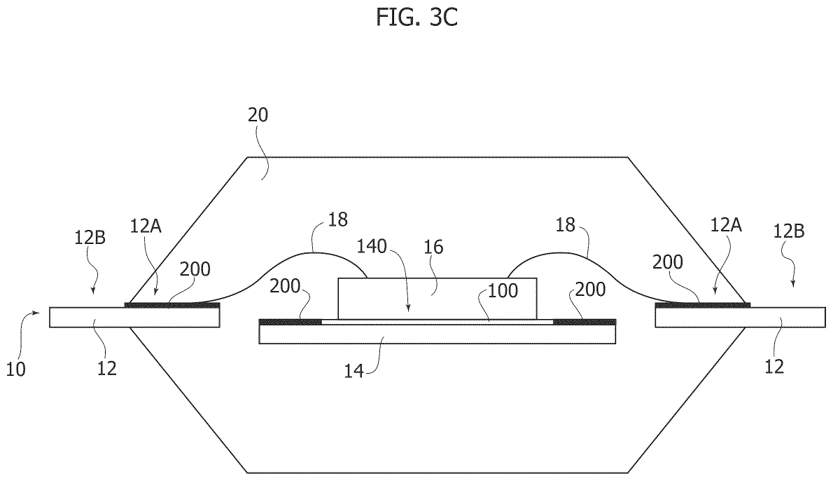

As illustrated in FIG. 2A, the metallic layer 100 covers the top/front surface of the substrate 10 as well as the back/bottom surface and side surfaces of the substrate 10 (that is, the substrate 10 illustrated in FIG. 2A is of the “fully plated” type). Alternatively, spot plating may be used as discussed below in connection with FIG. 3A.

FIG. 2B is illustrative of a patterned oxide layer 200 formed at a portion of the top/front surface of the die pad 14 and of the leads 12 via selective exposure to an oxidizing plasma OP.

As illustrated, selective exposure to an oxidizing plasma may be achieved via a batch plasma apparatus with the use of a filtering mask M as illustrated in FIG. 2B. A substantially uniform oxidizing plasma OP is formed in a vacuum chamber and projected toward the top/front surface of the substrate 10 (having the semiconductor die 16 arranged thereon as well as electrically conductive formations 18 provided between the die 16 and the leads 12).

As illustrated, the (substantially) uniform oxidizing plasma OP may be filtered via a filtering mask M provided over the substrate 10.

The filtering mask M counters the oxidizing plasma OP (that is, oxygen ions formed in the batch plasma chamber) to reach the surface of the substrate 10 at locations where it is not desired to form an oxide layer.

As visible in FIG. 2B, a distal portion 12B of the leads 12 may be left with a metallic layer 100 thereon, that is, an oxide layer 200 may be formed only at a (proximal) portion 12A of the top/front surface of the leads 12.

It is noted that selective exposure to an oxidizing plasma OP via an atmospheric plasma apparatus as described with reference to FIG. 1C could also be used in processing a device as illustrated in FIGS. 2A to 2C.

The thickness of the oxide layer 200 formed at the surface of the leadframe 10 may be controlled by varying the operating parameters of the batch plasma equipment (input power and/or exposure time, for instance). As discussed in the foregoing, oxide layer 200 having a thickness in the range between 2 nm and 300 nm, preferably between 10 nm and 100 nm, may be formed.

A cleaning step, possibly comprising exposing the assembly to a cleaning plasma CP (similarly to a cleaning step described with reference to FIG. 1D, for instance) may follow. For brevity, such an (optional) step is not illustrated in the sequence of processing steps of FIGS. 2A to 2C, but is shown in FIG. 1D.

As illustrated in FIG. 2C, an electrically insulating package 20 may be provided (via molding of an epoxy resin, for instance) that encapsulates the proximal portion 12A of the leads 12, thus contacting the oxide layer 200 formed thereon. The distal portion 12B of the leads 12 (having the surface metallic layer 100 left thereon) protrudes from the electrically insulating encapsulation 20.

FIGS. 3A to 3C illustrate a sequence of processing steps according to embodiments of the present description applied to a leadframe 10 (a QFP leadframe, for instance) having a metallic layer 100 formed (only) at a portion of the top/front surface thereof.

The metallic layer 100 may comprise silver material, for instance, formed at the die mounting region 140 (at the top/front surface of the die pad 14) and at the top/front surface of the leads 12.

Similar to the cases discussed in the foregoing, such a metallic layer 100 may be desirable in so far as it facilitates die mounting and wire bonding step.

FIG. 3A is illustrative of such a leadframe 10 having a (integrated circuit-IC) semiconductor die 16 arranged at a die mounting region of the top/front surface of a die pad 14, facilitated by the metallic layer 100 formed thereon (and via die-attach material provided/dispensed on the metallic layer 100, not visible in the figures for simplicity).

As illustrated, electrically conductive formations 18 (wires, for instance) are provided to electrically couple the semiconductor die 16 and selected leads 12 in the arrays of leads arranged around the die pad 14.

As illustrated, the surface metallic layer 100 (comprising silver material, for instance) is formed at the proximal portions 12A of the leads 12 that provide landing points for the electrically conductive formations 18 electrically coupling the leads 12 to the semiconductor die 16.

The substrate illustrated in FIG. 3A is thus exemplary of a substrate 10 having a metallic layer 100 provided (only) at a portion of a surface thereof (“spot” plating).

FIG. 3B is illustrative of a processing step where the metallic layer 100 (formed at a portion of the top/front surface of the substrate 10) is selectively exposed to an oxidizing plasma OP to form therein an oxide layer 200 (a silver oxide layer, for instance, when the metallic layer 100 comprises silver material).

As illustrated, selective exposure to the oxidizing plasma OP may be via an atmospheric plasma equipment, similarly to what has been described in the foregoing with reference to FIG. 1C.

A batch plasma equipment provided with a filtering mask M as described with reference to FIG. 2B may also be used in this case.

As illustrated in FIG. 3C, a protective plastic encapsulation 20 may be provided by molding an electrically insulating molding compound onto the assembly. The encapsulation 20 encapsulates the semiconductor die 16, the electrically conductive formations 18 as well as the proximal portions 12A of the leads 12 having the oxide layer 200 formed thereon. The distal portion 12B of the leads 12 protrudes from the electrically insulating encapsulation 20.

In summary, in embodiments described in relation to the figures, a semiconductor die 16 is arranged at a mounting region 140 of a surface of a substrate 10.

The substrate 10 (a leadframe, for instance) comprises electrically conductive leads 12 around a die pad 14 including the mounting region 140 (at its top/front surface).

The substrate 10 may be a leadframe of the type suitable for quad flat no leads (QFN) package or for quad flat package (QFP).

At least one portion of the surface of the substrate 10 comprises a metallic layer 100 including the mounting region 140.

The metallic layer 100 may also cover the back/bottom surface of the substrate 10, as well as the lateral surfaces (as illustrated in FIGS. 1A and 2A, for instance).

The metallic layer 100 is selectively exposed to an oxidizing plasma OP wherein a patterned oxide layer 200 comprising oxides of metallic material in the metallic layer 100 is formed at the surface of the substrate 10.

Selective exposure of the metallic surface layer 100 at the surface of the substrate (a QFN or a QFP leadframe, for instance) to an oxidizing plasma (OP) may be done via: an atmospheric plasma apparatus, and/or a batch plasma apparatus and a filtering mask M.

Subsequently, an electrically insulating encapsulation 20 (an epoxy resin, for instance) is molded onto the surface of the substrate 10 having the semiconductor die 16 arranged at the mounting region 140.

The electrically insulating encapsulation 20 encapsulates the semiconductor die 16 and contacts the patterned oxide layer 200 formed at the surface of the substrate 10. The oxides of metallic material in the patterned oxide layer 200 facilitate adhesion of the electrically insulating encapsulation 20 to the surface of the substrate 10.

The mounting region 140 may be located at a central region of the surface of the die pad 14. In such cases, advantageously, the metallic layer 100 may be selectively exposed to an oxidizing plasma OP to form the patterned oxide layer 200 at a peripheral region of the surface of the die pad 14 around the mounting region 140.

The metallic layer 100 may be exposed to an oxidizing plasma OP to form the patterned oxide layer 200 at the surface of the leads 12.

Embodiments as described herein may involve selectively exposing the metallic layer 100 to an oxidizing plasma OP and forming the patterned oxide layer 200 at the proximal portion 12A of the leads 12 leaving the metallic layer 100 unexposed at the distal portion of the leads 12. In such embodiments, molding the electrically insulating encapsulation 20 onto the surface of the substrate 10 having the semiconductor die 16 arranged at said mounting region 140 may comprise molding the electrically insulating encapsulation 20 onto the proximal portion of the leads 12 with the distal portion of the leads 12 protruding from the encapsulation 20. The oxides of metallic material in the patterned oxide layer 200 facilitate adhesion of the electrically insulating encapsulation 20 to the proximal portion of the leads 12.

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A method, comprising:
arranging a semiconductor die at a mounting region of a surface of a substrate, wherein the substrate comprises electrically conductive leads around a die pad including said mounting region and wherein said surface of the substrate comprises a metallic layer located at one or more portions of the substrate including said mounting region;
selectively exposing a portion less than all of said metallic layer to an oxidizing plasma to produce a patterned oxide layer comprising oxides of metallic material in the metallic layer at said surface of the substrate, and
molding an electrically insulating encapsulation onto the surface of the substrate, wherein the electrically insulating encapsulation encapsulates the semiconductor die and contacts the patterned oxide layer formed at said surface of the substrate, wherein the oxides of metallic material in the patterned oxide layer facilitate adhesion of the electrically insulating encapsulation to the surface of the substrate.

2. The method of claim 1, wherein said metallic layer comprises silver, and wherein said patterned oxide layer comprises silver oxides.

3. The method of claim 1, wherein the mounting region is located at a central region of the surface at the die pad, and wherein selectively exposing comprises selectively exposing said metallic layer to the oxidizing plasma at a peripheral region of the surface at the die pad around said mounting region.

4. The method of claim 1, wherein selectively exposing comprises selectively exposing said metallic layer to the oxidizing plasma at the surface of said leads.

5. The method of claim 4, wherein the leads have a proximal lead portion and a distal lead portion, wherein selectively exposing comprises selectively exposing the metallic layer to the oxidizing plasma at the proximal portion of the leads, and wherein molding the electrically insulating encapsulation comprises molding the electrically insulating encapsulation onto the proximal portion of the leads with the distal portion of the leads protruding from the encapsulation wherein the oxides of metallic material in the patterned oxide layer facilitate adhesion of the electrically insulating encapsulation to the proximal portion of the leads.

6. The method of claim 1, wherein selectively exposing the metallic surface layer to an oxidizing plasma is performed using an atmospheric plasma apparatus.

7. The method of claim 1, wherein selectively exposing the metallic surface layer to an oxidizing plasma is performed using a batch plasma apparatus and a filtering mask.

8. The method of claim 1, wherein said patterned oxide layer formed at the surface of the substrate has a thickness between 2 nm and 300 nm.

9. A device, comprising:
a substrate comprising electrically conductive leads around a die pad;
a metallic layer on a surface of the substrate;
a semiconductor die arranged at a mounting region of the surface of the die pad;
a plasma oxidized metallic layer including a patterned oxide layer comprising oxides of metallic material located at portions of metallic layer less than all of said metallic layer; and
an electrically insulating encapsulation molded onto the surface of the substrate, wherein the electrically insulating encapsulation encapsulates the semiconductor die and contacts the patterned oxide layer at said surface of the substrate, wherein the oxides of metallic material in the patterned oxide layer facilitate adhesion of the electrically insulating encapsulation to the surface of the substrate.

10. The device of claim 9, wherein the metallic layer comprises silver, and wherein said patterned oxide layer comprises silver oxides.

11. The device of claim 9, wherein the mounting region is located at a central region of the surface at the die pad, and wherein the patterned oxide layer at the surface of the substrate comprises an oxide layer formed at a peripheral region of the surface at the die pad around said mounting region.

12. The device of claim 9, wherein the patterned oxide layer at the surface of the substrate comprises an oxide layer at the surface of the leads.

13. The device of claim 12, wherein the patterned oxide layer is located at a proximal portion of the surface of the leads and the metallic layer is left at a distal portion of the leads, wherein the electrically insulating encapsulation molded onto the substrate contacts the oxide layer at the proximal portion of the surface of the leads, and wherein the distal portion of the leads having the metallic layer formed thereon protrude from the encapsulation.

14. The device of claim 9, wherein said patterned oxide layer formed at the surface of the substrate has a thickness between 2 nm and 300 nm.
